(19) United States
(12) Patent Application Publication
(10) Pub. No.: US 2026/0302139 A1
(43) Pub. Date: Oct. 1, 2026

(54) SUBSTRATE PROCESSING APPARATUS AND GAS SUPPLY METHOD

(71) Applicant: Tokyo Electron Limited, Tokyo (JP)

(72) Inventor: Kazuki FURUMIZU, Nirasaki City (JP)

(21) Appl. No.: 19/570,771

(22) Filed: Mar. 18, 2026

(30) Foreign Application Priority Data
Mar. 26, 2025 (JP) 2025-051578

(51) Int. Cl. H01J 37/32

(52) U.S. Cl. CPC H01J 37/32449; H01J 37/32834

(57) ABSTRACT

A substrate processing apparatus includes: a processing container accommodating a substrate; a flammable gas supply path supplying a flammable gas into the processing container; a covering structure, outside the processing container, including inner and outer covering bodies respectively including a first space partially accommodating the flammable gas supply path and a second space accommodating the inner covering body; a negative-pressure arrangement space where the covering structure is arranged; a non-flammable gas supply supplying a non-flammable gas to at least the first space; an exhauster exhausting gases in the first and second spaces; a pressure detector detecting information relating to pressures; and a controller controlling the non-flammable gas supply or the exhauster to adjust the pressure in the first space to be positive and the pressure in the second space to be lower than the arrangement space or to be higher than the arrangement space but lower than the first space.

### CROSS-REFERENCE TO RELATED APPLICATION

This application is based upon and claims the benefit of priority from Japanese Patent Application No. 2025-051578, filed on Mar. 26, 2025, the entire contents of which are incorporated herein by reference.

### TECHNICAL FIELD

The present disclosure relates to a substrate processing apparatus and a gas supply method.

### BACKGROUND

In Patent Document 1, a substrate processing apparatus (heat treatment apparatus) is described where a flammable gas is supplied to a processing container (chamber) that accommodates a substrate. This type of substrate processing apparatus is installed with a structure for exhausting the flammable gas to prevent ignition in an event of leakage of the flammable gas.

### PRIOR ART DOCUMENT

### Patent Document

Patent Document 1: Japanese Laid-Open Publication No. 2021-125497

### SUMMARY

According to one embodiment of the present disclosure, a substrate processing apparatus includes: a processing container capable of accommodating a substrate; a flammable gas supply path configured to supply a flammable gas into the processing container; a covering structure provided outside the processing container and configured to include an inner covering body including a first space for accommodating a portion of the flammable gas supply path and an outer covering body including a second space for accommodating the inner covering body; an arrangement space adjusted to a negative pressure and in which the covering structure is arranged; a non-flammable gas supply configured to supply a non-flammable gas to at least the first space; an exhauster capable of exhausting a gas in the first space and a gas in the second space; a pressure detector configured to detect information, respectively, relating to a pressure in the first space, a pressure in the second space, and a pressure in the arrangement space; and a controller, wherein, during supply of the flammable gas, the controller controls at least one selected from the group of the non-flammable gas supply and the exhauster based on the information from the pressure detector so as to adjust the pressure in the first space to a positive pressure and adjust the pressure in the second space to a pressure lower than the pressure in the arrangement space or to a pressure higher than the pressure in the arrangement space but lower than the pressure in the first space.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic plane view showing a substrate processing apparatus according to an embodiment.

FIG. 2 is a schematic cross-sectional view showing the substrate processing apparatus according to the embodiment.

FIG. 3 is a diagram showing an example of a gas supply system according to the embodiment.

FIG. 4 is a diagram schematically showing a gas box according to the embodiment.

FIG. 5 is a flowchart showing a gas supply method according to the embodiment.

FIG. 6A is a first diagram showing a gas leakage state of a covering structure according to the embodiment. FIG. 6B is a second diagram showing a gas leakage state of the covering structure according to the embodiment. FIG. 6C is a first diagram showing a gas leakage state of a covering structure according to a reference example. FIG. 6D is a second diagram showing a gas leakage state of the covering structure according to the reference example.

FIG. 7 is a diagram showing a gas box including a covering structure according to a modification.

FIG. 8A is a first diagram showing a gas leakage state of the covering structure according to the modification. FIG. 8B is a second diagram showing a gas leakage state of the covering structure according to the modification.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of the present disclosure will be described with reference to the drawings. In the drawings, the same components are denoted by like reference numerals, and repeated descriptions may be omitted.

### Substrate Processing Apparatus

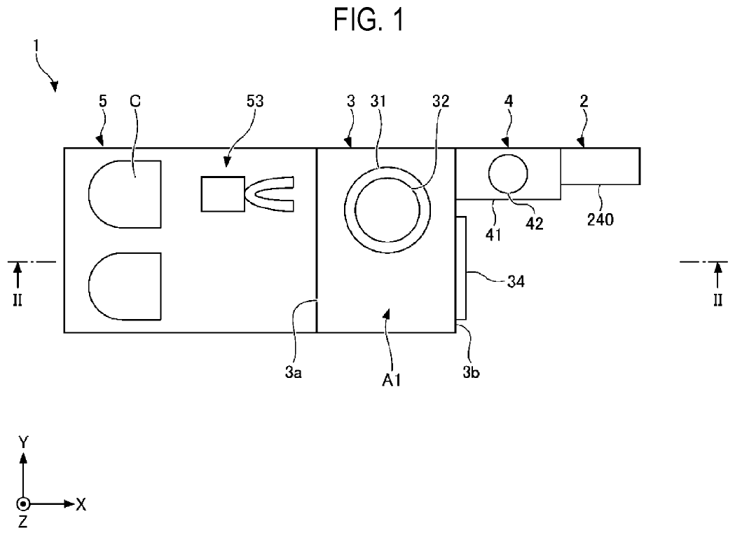

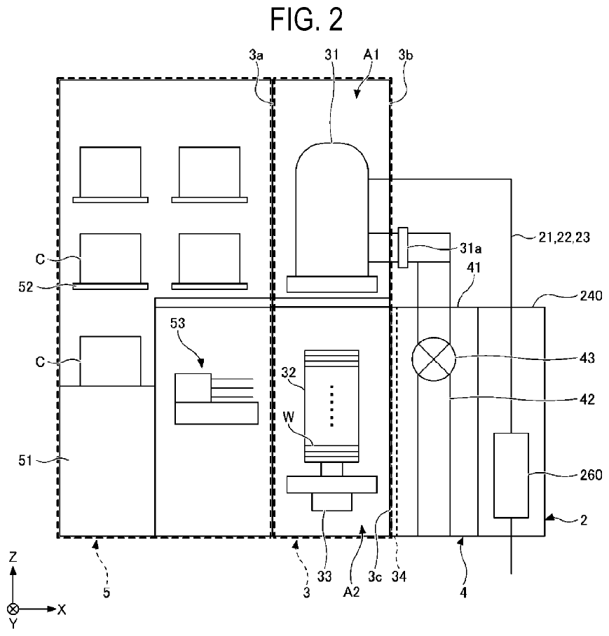

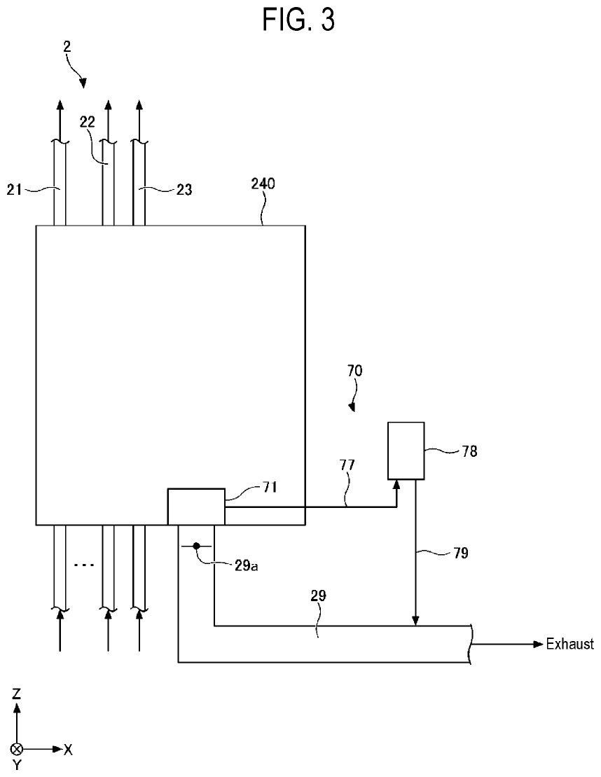

A substrate processing apparatus 1 according to an embodiment is described with reference to FIGS. 1 to 3. FIG. 1 is a schematic plane view showing the substrate processing apparatus 1 according to the embodiment. FIG. 2 is a schematic cross-sectional view showing the substrate processing apparatus 1 according to the embodiment. FIG. 2 corresponds to a cross-sectional view taken along line II-II in FIG. 1. FIG. 3 is a diagram showing an example of a gas supply system 2 according to the embodiment.

The substrate processing apparatus 1 includes a gas supply system 2 that performs a gas supply method according to the embodiment. The substrate processing apparatus 1 further includes a processing module 3, an exhaust unit 4, and a transfer module 5.

The transfer module 5 is arranged adjacent to a first sidewall 3a of the processing module 3. The transfer module 5 transfers substrates W to the processing module 3. The transfer module 5 includes a load port 51, a stocker 52, and a substrate deliverer 53.

The load port 51 is arranged on an X axis negative side of the transfer module 5. A plurality of (e.g., two) load ports 51 are arranged along a Y axis. However, the number of load ports 51 is not particularly limited. A cassette C is placed on the load port 51. The cassette C accommodates a plurality of (e.g., 25) substrates W. The cassette C is loaded in and out of the load port 51. The cassette C holds each substrate W horizontally. The cassette C is, for example, a FOUP (Front Opening Unified Pod).

A plurality of (e.g., two) stockers 52 are arranged along a Z axis on the X axis negative side of the transfer module 5. A plurality of (e.g., two) stockers 52 are arranged along the Z axis on an X axis positive side of the transfer module 5. A plurality of stockers 52 may be arranged along the Y axis. However, the number of stockers 52 is not particularly limited. The stockers 52 temporarily store cassettes C.

The substrate deliverer 53 transfers the substrates W between the cassette C placed on the load port 51 and a boat 32 in the processing module 3. The substrate deliverer 53 transfers, for example, a plurality of substrates W simultaneously. For example, the substrate deliverer 53 removes an unprocessed substrate W from the cassette C placed on the load port 51 and transfers the substrate W to the boat 32. For example, the substrate deliverer 53 removes a processed substrate W from the boat 32 and transfers the substrate W to the cassette C placed on the load port 51.

The transfer module 5 may include a cassette deliverer that delivers the cassette C between the load port 51 and the stocker 52. The transfer module 5 may include a loader for delivering substrates to and from the substrate deliverer 53, separately from the load port 51.

The processing module 3 includes a processing chamber A1 and a transfer chamber A2. The processing chamber A1 and the transfer chamber A2 are adjacent to each other along the Z axis. The transfer chamber A2 is located on a Z axis negative side of the processing chamber A1. The processing module 3 includes a first sidewall 3a and a second sidewall 3b. The first sidewall 3a is located on an X axis negative side of the processing module 3. The second sidewall 3b is located on an X axis positive side of the processing module 3. The first sidewall 3a and the second sidewall 3b are spaced apart in a direction extending along the X axis. Each of the first sidewall 3a and the second sidewall 3b extends from an end of the processing module 3 on a Y axis negative side to an end of the processing module 3 on a Y axis positive side. Each of the first sidewall 3a and the second sidewall 3b extends from a lower end of the transfer chamber A2 to an upper end of the processing chamber A1.

The processing module 3 includes a processing container 31, a boat 32, a driver 33, and a maintenance door 34.

The processing container 31 is arranged in the processing chamber A1. The processing container 31 is arranged between the first sidewall 3a and the second sidewall 3b in the direction extending along the X axis. The processing container 31 is heated by a heater (not shown). The processing container 31 is configured to be capable of accommodating the boat 32 holding the substrates W. A processing gas is supplied into the processing container 31 from the gas supply system 2. The processing gas is selected depending on a type of processing. The processing gas supplied into the processing container 31 is exhausted by the exhaust unit 4. Inside the processing container 31, a desired processing for the substrates W held on the boat 32 is carried out by the processing gas supplied from the gas supply system 2.

The boat 32 holds a plurality of substrates W in a shelf-like manner along the Z axis. The boat 32 is movable between a delivery position (the position shown in FIG. 2) and a processing position. The delivery position is a position below the processing container 31. The delivery position may be directly below the processing container 31. The processing position is a position accommodated within the processing container 31 and is a position above the delivery position. The processing position may be directly above the delivery position. For example, the boat 32 moves to the delivery position when delivering the substrates W to and from the substrate deliverer 53. For example, the boat 32 moves to the processing position when performing a desired processing on the substrates W.

The driver 33 is configured to move the boat 32 between the delivery position and the processing position. The driver 33 may include a boat elevator.

A maintenance opening 3c is provided at the second sidewall 3b. The maintenance opening 3c is provided on a Z axis negative side of the second sidewall 3b. The maintenance opening 3c is provided at a same height as the transfer chamber A2. The maintenance opening 3c is provided, for example, at a middle position in a direction extending along the Y axis. The maintenance opening 3c is an opening for performing maintenance on the processing module 3. The maintenance opening 3c is an opening for loading and unloading the processing container 31 and the boat 32 into and out of the processing module 3. Therefore, the maintenance opening 3c has a size that allows the processing container 31 and the boat 32 to pass therethrough. For example, the maintenance opening 3c is used when the processing container 31 is unloaded from an inside of the processing module 3 for replacement of the processing container 31 due to damage or for cleaning of the processing container 31. For example, the maintenance opening 3c is used when the boat 32 is unloaded from the inside of the processing module 3 for replacement of the boat 32 due to damage or for cleaning of the boat 32.

The maintenance door 34 rotates horizontally to open and close the maintenance opening 3c. When the maintenance door 34 is open, it is possible to load and unload the processing container 31 and the boat 32 through the maintenance opening 3c. In FIG. 1, the maintenance door 34 is shown in a closed state.

The exhaust unit 4 includes an exhaust box 41, an exhaust pipe 42, and a pressure control valve 43. The exhaust box 41 is arranged adjacent to the second sidewall 3b on the Y axis positive side of the processing module 3. The exhaust pipe 42 connects an exhaust port 31a of the processing container 31 to a vacuum pump (not shown). A portion of the exhaust pipe 42 between one end and the other end of the exhaust pipe 42 is accommodated inside the exhaust box 41. The pressure control valve 43 is provided inside the exhaust box 41. The pressure control valve 43 is interposed midway along the exhaust pipe 42. The pressure control valve 43 controls an internal pressure of the processing container 31 to a desired pressure.

As shown in FIG. 3, the gas supply system 2 includes gas supply lines 21, 22 and 23 connected to the processing container 31, a gas box 240 collectively accommodating the gas supply lines 21, 22 and 23, and an exhaust duct 29.

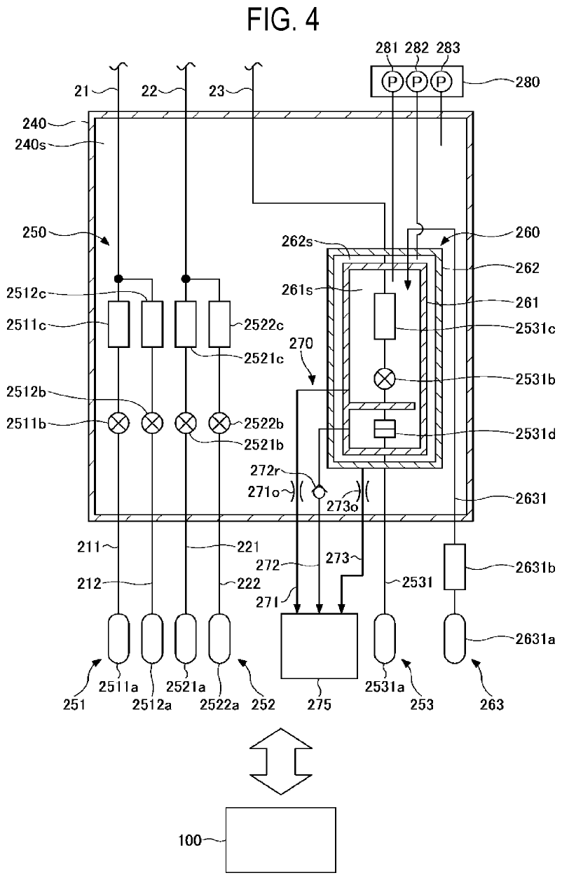

The gas box 240 is arranged adjacent to an X axis positive side of the exhaust box 41. The gas box 240 includes, for example, a rectangular parallelepiped arrangement space 240s (see FIG. 4) inside the gas box 240.

The gas supply lines 21, 22 and 23 supply processing gases into the processing container 31. As to be described in detail later, the gas supply lines 21 and 22 branch into multiple paths within the gas box 240, thereby forming multiple paths that extend to an outside of the gas box 240. Although the example in FIG. 3 shows three gas supply lines 21, 22 and 23, the number of gas supply lines is not limited to three.

One end of the exhaust duct 29 is connected to the gas box 240, and the other end of the exhaust duct 29 is connected to an external exhaust mechanism (e.g., a factory exhaust facility) (not shown). The exhaust duct 29 creates a negative pressure in the arrangement space 240s of the gas box 240 based on suction by the exhaust mechanism when a gas is supplied. An exhaust damper 29a that adjusts an amount of a gas exhausted is also provided inside the exhaust duct 29. A pressure in the arrangement space 240s is adjusted by adjustment of the exhaust amount with the exhaust damper 29a.

Further, the gas supply system 2 may include a gas detection device 70 that detects a gas leaking in the gas box 240. The gas detection device 70 includes, for example, a suction 71 provided at an inlet of the exhaust duct 29, a suction line 77 connected to the suction 71, a gas detector 78 that detects a gas flowing in from the suction line 77, and an exhaust line 79 that allows a gas to flow from the gas detector 78 to the exhaust duct 29.

The gas box 240 for the gas supply system 2 provided in the substrate processing apparatus 1 according to the embodiment is described in more detail below with reference to FIG. 4. FIG. 4 is a diagram schematically showing the gas box 240 according to the embodiment.

The gas box 240 includes the arrangement space 240s that is partitioned from a space of the exhaust unit 4. The gas box 240 is able to airtightly seal the arrangement space 240s. The pressure in the arrangement space 240s is adjusted to a negative pressure based on an operation of a suction device (not shown) provided downstream of the exhaust duct 29 during substrate processing.

The gas box 240 forms a unit structure in which gas supply paths, valves, flow rate adjusters, and the like are accommodated together within the gas box 240. Thus, the gas box 240 is able to facilitate maintenance of the gas supply system. Specifically, inside the gas box 240, each of the gas supply lines 21 and 22 branches into multiple (two) lines to form a pipe part 250. Further, the gas box 240 accommodates a covering structure 260, a portion of an exhauster 270, and the like.

The pipe part 250 includes upstream supply lines 211 and 212 connected to the gas supply line 21, and upstream supply lines 221 and 222 connected to the gas supply line 22. The pipe part 250 accommodates the upstream supply lines 211, 212, 221 and 222, on-off valves and flow rate adjusters inside the gas box 240. For example, the pipe part 250 is configured by combining a raw material gas supply 251, a reaction gas supply 252, a flammable gas supply 253, and the like.

The raw material gas supply 251 supplies a raw material gas and an auxiliary gas such as an inert gas (purge gas) or an additive gas via the gas supply line 21. The raw material gas supply 251 includes a raw material gas source 2511a at an upstream end of the upstream supply line 211 on one branch, and an auxiliary gas source 2512 a at an upstream end of the upstream supply line 212 on another branch. The raw material gas source 2511a and the auxiliary gas source 2512a are high-pressure tanks provided outside.

An on-off valve 2511b and a flow rate adjuster 2511c are provided in the branched upstream supply line 211. The on-off valve 2511b switches between supplying the raw material gas from the raw material gas source 2511a and stopping the supply of the raw material gas by opening and closing a flow path of the upstream supply line 211. In the flow rate adjuster 2511c, for example, a mass flow controller is applied to adjust a flow rate of the raw material gas when the raw material gas is supplied.

Further, an on-off valve 2512b and a flow rate adjuster 2512c are provided in the branched upstream supply line 212. The on-off valve 2512b switches between supplying the auxiliary gas from the auxiliary gas source 2512a and stopping the supply of the auxiliary gas by opening and closing a flow path of the upstream supply line 212. In the flow rate adjuster 2512c, for example, a mass flow controller is applied to adjust a flow rate of the auxiliary gas when the auxiliary gas is supplied.

Similarly, the reaction gas supply 252 supplies a reaction gas and an auxiliary gas such as an inert gas (purge gas) or an additive gas via the gas supply line 22. The reaction gas supply 252 includes a reaction gas source 2521a at an upstream end of the branched upstream supply line 221, and an auxiliary gas source 2522a at an upstream end of the branched upstream supply line 222. The reaction gas source 2521a and the auxiliary gas source 2522a are high-pressure tanks provided outside.

An on-off valve 2521b and a flow rate adjuster 2521c are provided in the branched upstream supply line 221. The on-off valve 2521b switches between supplying the reaction gas from the reaction gas source 2521a and stopping the supply of the reaction gas by opening and closing a flow path of the upstream supply line 221. In the flow rate adjuster 2521c, for example, a mass flow controller is applied to adjust a flow rate of the reaction gas when the reaction gas is supplied.

Further, an on-off valve 2522b and a flow rate adjuster 2522c are provided in the branched upstream supply line 222. The on-off valve 2522b switches between supplying the auxiliary gas from the auxiliary gas source 2522a and stopping the supply of the auxiliary gas by opening and closing a flow path of the upstream supply line 222. In the flow rate adjuster 2522c, for example, a mass flow controller is applied to adjust a flow rate of the auxiliary gas when the auxiliary gas is supplied.

The flammable gas supply 253 includes a flammable gas supply path 2531 connected to the gas supply line 23 to form an upstream supply line. A flammable gas source 2531a is provided at an upstream end of the flammable gas supply path 2531. The flammable gas source 2531a is an external high-pressure tank that stores a flammable gas. Examples of the flammable gas include hydrogen, methane, ethane, propane, carbon monoxide, ethanol, and others, and an appropriate flammable gas is prepared depending on a type of substrate processing. In the embodiment, upstream supply lines branched from the gas supply line 23 are not presented, but the flammable gas supply 253 may be connected to a plurality of gas sources by branching the gas supply line 23, just like the gas supply lines 21 and 22. In this case, a joint at a branched portion may be provided in the covering structure 260, which is described later.

The flammable gas supply 253 includes an on-off valve 2531b, a flow rate adjuster 2531c, a joint 2531d, and the like on the flammable gas supply path 2531. The on-off valve 2531b switches between supplying the flammable gas from the flammable gas source 2531a and stopping the supply of the flammable gas by opening and closing a flow path of the flammable gas supply path 2531. In the flow rate adjuster 2531c, for example, a mass flow controller is applied to adjust a flow rate of the flammable gas when the flammable gas is supplied. The joint 2531d connects a plurality of pipes to each other on the flammable gas supply path 2531. Although not shown in FIG. 4, joints may be provided on the gas supply lines 21 and 22.

The flammable gas supplied by the flammable gas supply 253 may ignite when it leaks outside (including the arrangement space 240s). Therefore, the gas box 240 is structured to seal off a location in the flammable gas supply path 2531 where the flammable gas is likely to leak. Examples of the location where the flammable gas is likely to leak include locations where the pipes of the flammable gas supply path 2531 are connected to equipment (the on-off valve 2531b and the flow rate adjuster 2531c). Another location where the flammable gas is likely to leak is the joint 2531d where the pipes are connected to each other. In particular, the joint 2531d is likely to be poorly connected during initial installation of the pipes, and may easily become a location where the flammable gas leaks.

The covering structure 260 is a structure that collectively covers the on-off valve 2531b, the flow rate adjuster 2531c, and the joint 2531d on the flammable gas supply path 2531. Specifically, the covering structure 260 forms a double structure including an inner covering body 261 that accommodates the on-off valve 2531b, the flow rate adjuster 2531c and the joint 2531d, and an outer covering body 262 that accommodates the inner covering body 261.

The inner covering body 261 is formed in a box shape including a first space 261s that is capable of accommodating the on-off valve 2531b, the flow rate adjuster 2531c, and the joint 2531d. The inner covering body 261 may divide the first space 261s into a plurality of spaces. For example, in FIG. 4, the first space 261s is divided into a space that accommodates the on-off valve 2531b and the flow rate adjuster 2531c, and a space that accommodates the joint 2531d. However, these spaces are in communication with each other, allowing a gas to move within the first space 261s.

The outer covering body 262 is formed in a box shape that is slightly larger than the inner covering body 261, and includes a second space 262s inside. In a state where the inner covering body 261 is accommodated in the outer covering body 262, an appropriate gap is created between an outer surface of the inner covering body 261 and an inner surface of the outer covering body 262. In other words, the second space 262s of the outer covering body 262 has a volume that allows the inner covering body 261 to be accommodated in the second space 262s, while leaving some space.

The covering structure 260 also includes a non-flammable gas supply 263 that supplies a non-flammable gas to the first space 261s of the inner covering body 261. The non-flammable gas supply 263 includes a non-flammable gas supply path 2631 that communicates with the first space 261s of the inner covering body 261. A non-flammable gas source 2631a is provided at an upstream end of the non-flammable gas supply path 2631. The non-flammable gas source 2631a is an externally provided high-pressure tank that stores a non-flammable gas. Examples of the non-flammable gas include nitrogen, carbon dioxide, and others.

The non-flammable gas supply 263 includes a flow rate adjuster 2631b and an on-off valve (not shown) on the non-flammable gas supply path 2631. In the flow rate adjuster 2631b, for example, a mass flow controller is applied to adjust a flow rate of the non-flammable gas when the non-flammable gas is supplied. The on-off valve switches between supplying the non-flammable gas from the non-flammable gas source 2631a and stopping the supply of the non-flammable gas by opening and closing a flow path of the non-flammable gas supply path 2631. While FIG. 4 shows an example in which the flow rate adjuster 2631b is installed outside the gas box 240, the flow rate adjuster 2631b, the on-off valve, and the like may be provided inside the gas box 240.

A pressure inside the first space 261s of the inner covering body 261 of the covering structure 260 is adjusted to a positive pressure by supplying the non-flammable gas from the non-flammable gas supply 263. In an event of leakage of the flammable gas, it is possible for the non-flammable gas supplied to the first space 261s to promote dilution of the flammable gas by mixing with the flammable gas.

Further, the exhauster 270 is connected to the covering structure 260 and has a function of exhausting a gas from an interior of the covering structure 260. Specifically, the exhauster 270 includes a first inner exhaust path 271 that communicates with the first space 261s of the inner covering body 261, a second inner exhaust path 272 that also communicates with the first space 261s, and an outer exhaust path 273 that communicates with the second space 262s of the outer covering body 262. The exhauster 270 further includes a suction device 275 that is connected to the first inner exhaust path 271, the second inner exhaust path 272, and the outer exhaust path 273 to apply a suction force to the respective paths.

The first inner exhaust path 271 is a path that continuously exhausts a gas from the first space 261s during supply of the flammable gas by the flammable gas supply 253. An orifice 271o and the like are provided midway along the first inner exhaust path 271. The orifice 271o keeps constant an amount of the gas exhausted from the first space 261s.

The second inner exhaust path 272 is a path for emergency exhaust of a gas when the pressure in the first space 261s exceeds a predetermined value. For this reason, a relief valve 272r and the like are provided midway along the second inner exhaust path 272. The relief valve 272r is normally closed and is opened when the pressure exceeds a predetermined value, allowing the gas to be exhausted.

The outer exhaust path 273 is a path that continuously exhausts a gas from the second space 262s during the supply of the flammable gas by the flammable gas supply 253. An orifice 273o and the like are provided midway along the outer exhaust path 273. The orifice 273o keeps constant an amount of the gas exhausted from the second space 262s.

It is possible for the covering structure 260 and the exhauster 270 configured as described above to appropriately adjust a pressure inside the covering structure 260 during the supply of the flammable gas by supplying the non-flammable gas with the non-flammable gas supply 263 and exhausting gases with the exhauster 270. Specifically, the non-flammable gas is supplied to the first space 261s of the inner covering body 261 by the non-flammable gas supply 263, while gases are exhausted by the exhauster 270. However, by adjusting a gas flow rate in the first inner exhaust path 271, an amount of the non-flammable gas supplied by the non-flammable gas supply 263 increases, and the pressure in the first space 261s is adjusted to a positive pressure.

Meanwhile, a gas is exhausted from the second space 262s of the outer covering body 262 by the exhauster 270. Although a gas may move into the second space 262s through minute gaps in the inner covering body 261, an amount of the gas that moves in is small. Therefore, a pressure in the second space 262s is adjusted to a negative pressure. Then, as the exhauster 270 continuously sucks the gas, the pressure (negative pressure) in the second space 262s becomes lower than the pressure in the arrangement space 240s of the gas box 240.

In other words, when the flammable gas is supplied, a pressure relationship within the gas box 240 is: pressure (negative pressure) in the second space 262s<pressure (negative pressure) in the arrangement space 240s<pressure (positive pressure) in the first space 261s. By creating such a pressure relationship, it is possible for the gas box 240 to restrict movement of the flammable gas into the arrangement space 240s even when the flammable gas leaks from the flammable gas supply path 2531 into the first space 261s.

The gas box 240 is also installed with a pressure detector 280 for monitoring the above-mentioned pressure relationship. The pressure detector 280 includes, for example, a first pressure sensor 281 that detects the pressure in the first space 261s, a second pressure sensor 282 that detects the pressure in the second space 262s, and a third pressure sensor 283 that detects the pressure in the arrangement space 240s. The pressure detector 280 is not limited to this pressure sensor configuration, and may include, for example, a first manometer that detects a differential pressure between the first space 261s and the second space 262s, and a second manometer that detects a differential pressure between the second space 262s and the arrangement space 240s.

A controller 100 of the substrate processing apparatus 1 is a computer including a processor, a memory, an input/output interface, and a communication interface (not shown). The processor is one or a combination of a central processing unit (CPU), a graphics processing unit (GPU), an application-specific integrated circuit (ASIC), a field-programmable gate array (FPGA), a circuit made up of multiple discrete semiconductors, and the like. The memory includes a main memory device made up of a semiconductor memory or the like, and an auxiliary memory device made up of a disk, a semiconductor memory (flash memory) or the like. The memory may be configured by appropriately combining a volatile memory and a non-volatile memory (e.g., a compact disc, a digital versatile disc (DVD), a hard disk, a flash memory, etc.). The processor reads and executes programs and substrate processing recipes stored in the memory to control each component of the substrate processing apparatus 1 to perform substrate processing. In other words, the controller 100 of the present disclosure is an electronic circuit including a CPU, a GPU, an ASIC, an FPGA, etc., and is configured to perform various control operations described herein by executing instruction codes stored in the memory or by being designed as a circuit for a specific application.

During supply of a gas, the controller 100 acquires detection information from the pressure detector 280 and, based on this detection information, adjusts an operation of the non-flammable gas supply 263 (a supply amount of a non-flammable gas) and an operation of the exhauster 270 (an exhaust amount of a gas). Further, during the supply of the flammable gas, it is also possible for the controller 100 to detect leakage of the flammable gas from the flammable gas supply path 2531 by monitoring an increase in the pressure in the first space 261s, or the like.

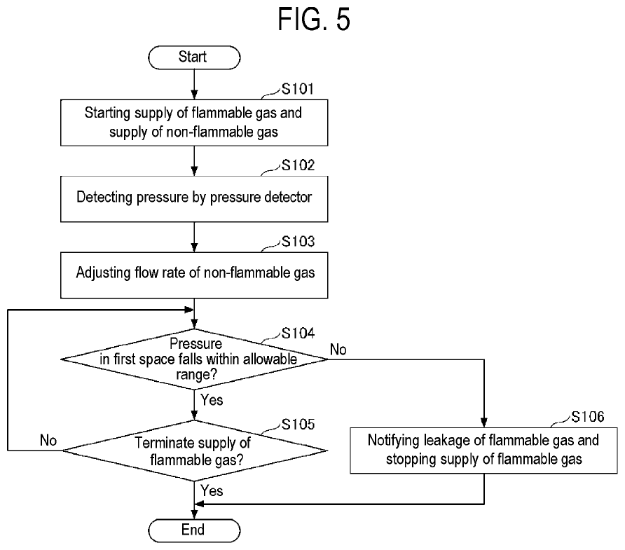

The substrate processing apparatus 1 according to the embodiment is basically configured as described above, and an operation during supply of a flammable gas (gas supply method) is described below with reference to FIG. 5. FIG. 5 is a flowchart showing a gas supply method according to an embodiment.

When supplying a flammable gas, the controller 100 of the substrate processing apparatus 1 sequentially executes a processing flow shown in FIG. 5.

Specifically, the controller 100 first controls the flammable gas supply 253 to supply a flammable gas, and also controls the non-flammable gas supply 263 to supply a non-flammable gas to the covering structure 260, and controls the exhauster 270 to exhaust a gas from the covering structure 260 (step S101).

Then, during the supply of the flammable gas, the pressure detector 280 detects the pressures in the first space 261s, the second space 262s, and the arrangement space 240s, and transmits the detection information to the controller 100 (step S102). For example, the controller 100 calculates the differential pressure between the first space 261s and the second space 262s and the differential pressure between the second space 262s and the arrangement space 240s based on the received detection information. Further, it is also possible for the controller 100 to monitor, based on the detection information, whether the above-mentioned relationship of the pressure in the second space 262s<the pressure in the arrangement space 240s< the pressure in the first space 261s is established.

Further, the controller 100 uses information such as the differential pressure to adjust the flow rate of the non-flammable gas supplied by the non-flammable gas supply 263 and/or adjust the amount of a gas exhausted by the exhauster 270 (step S103). As a result, when supplying the flammable gas, it is possible for the controller 100 to appropriately adjust an amount of the non-flammable gas in the covering structure 260 so as to continuously maintain the relationship of the pressure in the second space 262s< the pressure in the arrangement space 240s<the pressure in the first space 261s.

Further, in order to recognize a leakage of the flammable gas from the flammable gas supply path 2531, the controller 100 monitors the pressure in the first space 261s and determines whether the pressure in the first space 261s after stabilization is within an allowable range (step S104). If the pressure in the first space 261s is within the allowable range (step S104: YES), it is determined that the flammable gas is not leaking, and the process proceeds to step S105.

In step S105, the controller 100 compares the substrate processing recipe (processing period) with an actual processing period to determine whether or not to terminate the supply of the flammable gas. When the supply of the flammable gas is to be continued (step S105: NO), the process returns to step S104, and the same determination is repeated. On the other hand, when the supply of the flammable gas is to be terminated (step S105: YES), a termination processing or the like is performed to terminate this processing flow. This termination processing may include stopping the supply of the flammable gas or other gases supplied.

On the other hand, if the pressure in the first space 261s sharply rises to fall outside the allowable range when the pressure is stable (step S104: NO), it indicates that the flammable gas is leaking. In this case, the controller 100 proceeds to step S106, notifies a user of leakage of the flammable gas via a user interface (not shown), and interlocks the flammable gas supply 253 to stop the supply of the flammable gas. This makes it possible to quickly notify the user of the substrate processing apparatus 1 of an abnormality even when the flammable gas leaks. The substrate processing apparatus 1 may enhance accuracy of detecting leakage of the flammable gas by utilizing pressure detection of the pressure detector 280 and gas detection information from the gas detection device 70.

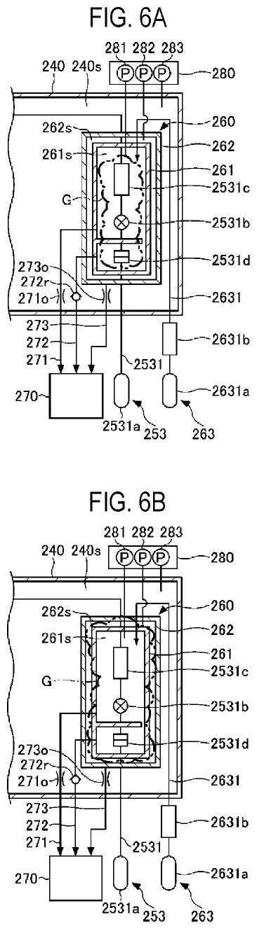

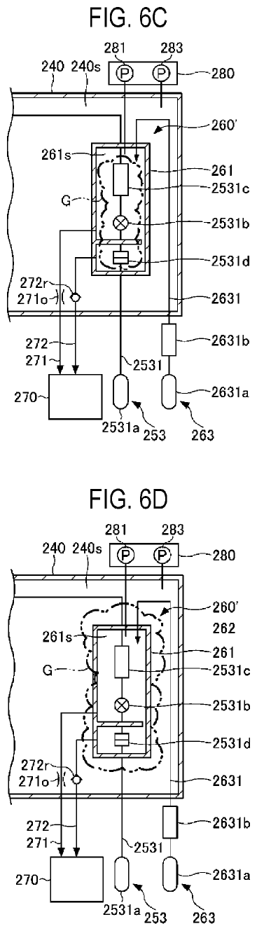

The covering structure 260 according to the embodiment has the double structure including the inner covering body 261 and the outer covering body 262, and the pressure relationship is such that the pressure in the second space 262s< the pressure in the arrangement space 240s< the pressure in the first space 261s, which makes it possible to suppress leakage of the flammable gas to an outside. Next, behavior of the flammable gas leaking from the flammable gas supply path 2531 is specifically described with reference to FIGS. 6A to 6D. FIG. 6A is a first diagram showing a gas leakage state of the covering structure 260 according to the embodiment. FIG. 6B is a second diagram showing a gas leakage state of the covering structure 260 according to the embodiment. FIG. 6C is a first diagram showing a gas leakage state of a covering structure 260′ according to a reference example. FIG. 6D is a second diagram showing a gas leakage state of the covering structure 260′ according to the reference example.

First, the covering structure 260′ according to the reference example is described. As shown in FIGS. 6C and 6D, the covering structure 260′ has a single-layer structure including only the inner covering body 261. With this structure, when a flammable gas G leaks from the joint 2531d, for example, the flammable gas G easily moves from the first space 261s, which is kept under a positive pressure, to the external arrangement space 240s, which is kept under a negative pressure. In other words, even if the gas in the first space 261s is exhausted by the exhauster 270, the positive pressure urges the gas leaked from the joint 2531d to move outside the covering structure 260. Since the inner covering body 261 does not hermetically seal the first space 261s, the leaked flammable gas G moves into the arrangement space 240s of the gas box 240 in which the pressure is adjusted to a negative pressure. In some cases, the flammable gas G may ignite depending on a configuration of the gas box 240.

In contrast, the covering structure 260 according to the embodiment has the double structure including the inner covering body 261 and the outer covering body 262, and makes it possible to effectively prevent the flammable gas G from moving into the arrangement space 240s even if the flammable gas G leaks from the flammable gas supply 253. That is, as shown in FIGS. 6A and 6B, when the flammable gas G leaks from the joint 2531d, for example, the flammable gas G moves from the first space 261s, which is kept under a positive pressure, to the outer second space 262s. However, the pressure in the second space 262s is adjusted to a lower pressure than the pressure in the arrangement space 240s based on the exhaust by the exhauster 270.

Therefore, gases in the arrangement space 240s also flow into the second space 262s, which makes it possible to prevent movement of gases from the second space 262s to the arrangement space 240s. Accordingly, even when the flammable gas G moves from the first space 261s to the second space 262s, the flammable gas G remains in the second space 262s. Further, suction by the exhauster 270 causes the flammable gas G to be exhausted only to the exhauster 270. As a result, the flammable gas G does not ignite in the arrangement space 240s.

As described above, it is possible for the substrate processing apparatus 1 according to this embodiment to reliably prevent ignition even in an event of flammable gas leakage by adjusting the pressures in the covering structure 260 accommodating the flammable gas supply 253. Further, the flammable gas in the first space 261s is also exhausted from the first inner exhaust path 271 and the second inner exhaust path 272 with the relief valve 272r open. Accordingly, it is possible to shorten residence time of the flammable gas in the covering structure 260.

The technical concept of the present disclosure is not limited to the above-described embodiment, and various modifications are conceivable. For example, in the above-described embodiment, the batch-type substrate processing apparatus 1 that processes a plurality of substrates W has been described as the substrate processing apparatus. However, the substrate processing apparatus is not limited thereto, and may be a single-substrate-type apparatus that processes each substrate W individually. In addition, the substrate processing apparatus may be a plasma processing apparatus.

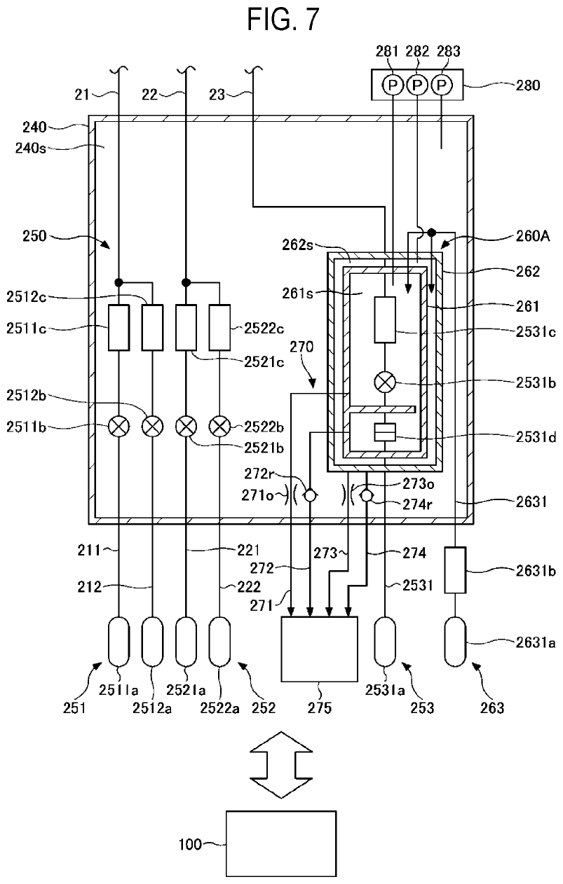

FIG. 7 is a diagram showing a gas box 240 including a covering structure 260A according to a modification. The covering structure 260A according to the modification shown in FIG. 7 differs from the covering structure 260 according to the above-described embodiment in that a non-flammable gas is also supplied to the second space 262s of the outer covering body 262, and the non-flammable gas is exhausted from the second space 262s by the exhauster 270.

Specifically, in the covering structure 260A, the non-flammable gas supply path 2631 is branched into two branch paths midway, and the branch paths are connected to the first space 261s of the inner covering body 261 and the second space 262s of the outer covering body 262, respectively. This allows the non-flammable gas to be supplied to the first space 261s and the second space 262s.

Further, the exhauster 270 includes a plurality of paths connected to the second space 262s of the outer covering body 262. That is, the exhauster 270 includes a first outer exhaust path 273 including an orifice 273o and a second outer exhaust path 274 including a relief valve 274r. In this case, the first outer exhaust path 273 serves as a path for continuously exhausting the non-flammable gas from the second space 262s. On the other hand, the second outer exhaust path 274 serves as a path that is opened at a pressure higher than a predetermined level in an emergency such as flammable gas leakage to exhaust the gas.

The covering structure 260A and the exhauster 270 configured as described above makes it possible to appropriately adjust the pressures inside the covering structure 260 during the supply of the flammable gas by supplying the non-flammable gas with the non-flammable gas supply 263 and exhausting the gas with the exhauster 270. Specifically, the non-flammable gas is supplied to the first space 261s of the inner covering body 261 by the non-flammable gas supply 263, while being exhausted by the exhauster 270. However, since an amount of the non-flammable gas supplied by the non-flammable gas supply 263 is large, the pressure in the first space 261s is adjusted to a positive pressure.

Meanwhile, the non-flammable gas is also supplied to the second space 262s of the outer covering body 262 by the non-flammable gas supply 263, while being exhausted by the exhauster 270. However, an amount of gas exhausted from the second space 262s is set to be greater than an amount of gas exhausted from the first space 261s by using the orifice 273o or the like. Therefore, the pressure in the second space 262s is adjusted to be lower than the pressure in the first space 261s, even if the pressure in the second space 262s is a positive pressure.

In other words, when the covering structure 260A is applied, the pressure relationship within the gas box 240 is such that, when the flammable gas is supplied, the pressure (negative pressure) in the arrangement space 240s<the pressure (positive pressure) in the second space 262s< the pressure (positive pressure) in the first space 261s.

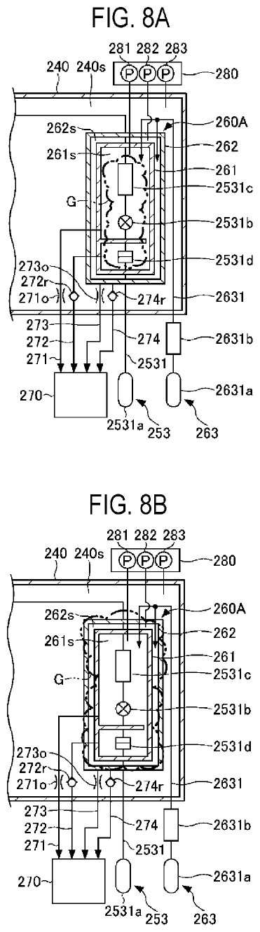

FIG. 8A is a first diagram showing a gas leakage state of the covering structure 260A according to the modification. FIG. 8B is a second diagram showing a gas leakage state of the covering structure 260A according to the modification. By forming the pressure relationship as described above, it is possible for the gas box 240 to restrict the movement of the flammable gas into the arrangement space 240s, as shown in FIGS. 8A and 8B, even if the flammable gas leaks from the flammable gas supply 253 into the first space 261s.

For example, in a case where the flammable gas G leaks from the joint 2531d, the flammable gas G gradually moves from the first space 261s, which is kept under a positive pressure, to the outer second space 262s, which is also kept under a positive pressure. At this time, the exhauster 270 increases gas exhaust capacity by opening the relief valve 272r of the second inner exhaust path 272. Further, the flammable gas that has moved to the second space 262s is subjected to the exhaust suction force even in the second space 262s by the exhauster 270. The exhauster 270 increases the gas exhaust capacity by opening the relief valve 274r of the second outer exhaust path 274. As a result, most of the flammable gas that has moved to the second space 262s is sucked by the exhauster 270.

Even if the flammable gas leaks from the outer covering body 262 into the arrangement space 240s, an amount of the flammable gas leaked is small and the flammable gas is diluted in the arrangement space 240s, whereby the ignition of the flammable is prevented. Therefore, even in the case of flammable gas leakage, the covering structure 260A according to the modification makes it possible to appropriately exhaust the flammable gas.

### Supplementary Note

Technical concepts and effects of the present disclosure described in the above embodiments are set forth below.

A first aspect of the present disclosure is directed to a substrate processing apparatus (substrate processing apparatus 1) including: a processing container 31 capable of accommodating a substrate W; a flammable gas supply path 2531 configured to supply a flammable gas into the processing container; a covering structure 260 or 260A provided outside the processing container and configured to include an inner covering body 261 including a first space 261s for accommodating a portion of the flammable gas supply path 2531 and an outer covering body 262 including a second space 262s for accommodating the inner covering body 261; an arrangement space 240s configured to accommodate the covering structure 260 or 260A of the flammable gas supply path 2531 and kept under a negative pressure; a non-flammable gas supply 263 configured to supply a non-flammable gas to at least the first space 261s; an exhauster 270 capable of exhausting a gas in the first space 261s and a gas in the second space 262s; a pressure detector 280 configured to detect information, respectively, relating to a pressure in the first space 261s, a pressure in the second space 262s, and a pressure in the arrangement space 240s; and a controller 100, wherein, during supply of the flammable gas, the controller 100 controls at least one selected from the group of the non-flammable gas supply 263 and the exhauster 270 based on the information from the pressure detector 280 so as to adjust the pressure in the first space 261s to a positive pressure and adjust the pressure in the second space 262s to a pressure lower than the pressure in the arrangement space 240s or to a pressure higher than the pressure in the arrangement space 240s but lower than the pressure in the first space 261s.

As described above, the substrate processing apparatus (substrate processing apparatus 1) makes it possible to significantly reduce leakage of the flammable gas to an outside by adjusting the pressures in the first space 261s and the second space 262s of the covering structure 260 or 260A even if the flammable gas leaks inside the covering structure 260 or 260A. That is, by adjusting the pressures in the first space 261s and the second space 262s, it is possible for the covering structure 260 or 260A to smoothly exhaust the flammable gas that has leaked into the first space 261s from the first space 261s and the second space 262s to the exhauster 270. As a result, it is possible for the substrate processing apparatus to reliably prevent ignition when the flammable gas leaks.

Further, the controller 100 adjusts a flow rate of the non-flammable gas supplied by the non-flammable gas supply 263 based on the information from the pressure detector 280. By adjusting the flow rate of the non-flammable gas, it is possible for the substrate processing apparatus to easily adjust the pressure in the first space 261s, the pressure in the second space 262s, and the pressure in the arrangement space 240s to meet the above-mentioned relationship.

Further, the controller 100 determines whether or not the flammable gas leaks from the flammable gas supply path 2531 to the first space 261s based on the information from the pressure detector 280, and stops the supply of the flammable gas through the flammable gas supply path 2531 when the flammable gas leaks. Accordingly, it is possible for the substrate processing apparatus to smoothly stop the supply of the flammable gas even if the flammable gas leaks in an unseen location within the covering structure 260 or 260A.

Further, the covering structure 260 or 260A accommodates, in the first space 261s, an on-off valve 2531b, a flow rate adjuster 2531c and a joint 2531d provided in the flammable gas supply path 2531. Accordingly, components that are prone to gas leakage in the flammable gas supply path 2531 are accommodated in the first space 261s of the covering structure 260 or 260A, making it possible to reduce leakage of the flammable gas to the outside.

The substrate processing apparatus further includes a gas box 240 configured to form the arrangement space 240s, and a plurality of pipes and a plurality of valves are arranged inside the gas box 240 and outside the covering structure 260 or 260A. As a result, even in the configuration in which the plurality of pipes and the plurality of valves are accommodated inside the gas box 240, it is possible to significantly reduce leakage of the flammable gas inside the covering structure 260 or 260A, thus preventing ignition.

The exhauster 270 includes a first path (first inner exhaust path 271) including an orifice 271o capable of adjusting a flow rate of the gas exhausted from the first space 261s, and a second path (second inner exhaust path 272) including a relief valve 272r capable of being opened to exhaust the gas when the pressure in the first space 261s reaches a predetermined level or higher. Accordingly, it is possible for the substrate processing apparatus to immediately exhaust the flammable gas together with the non-flammable gas from the two paths in the first space 261s in an event of flammable gas leakage.

Further, the non-flammable gas supply 263 also supplies the non-flammable gas to the second space 262s. Accordingly, even when the flammable gas leaks and moves to the second space 262s, it is possible for the flammable gas to be effectively diluted by the non-flammable gas in the second space 262s.

Further, at least one selected from the group of the non-flammable gas supply 263 and the exhauster 270 adjusts the pressure in the second space 262s to a positive pressure lower than the pressure in the first space 261s. By adjusting the pressure in the second space 262s to a positive pressure in this manner, the substrate processing apparatus makes it possible to significantly reduce an amount of the flammable gas that moves from the first space 261s to the second space 262s in an event of flammable gas leakage.

A second aspect of the present disclosure is directed to a gas supply method for a substrate processing apparatus (substrate processing apparatus 1) including a processing container 31 capable of accommodating a substrate W, a flammable gas supply path 2531 configured to supply a flammable gas into the processing container, a covering structure 260 or 260A provided outside the processing container and configured to include an inner covering body 261 including a first space 261s for accommodating a portion of the flammable gas supply path 2531 and an outer covering body 262 including a second space 262s for accommodating the inner covering body 261, an arrangement space 240s configured to accommodate the covering structure 260 or 260A in the flammable gas supply path 2531 and kept under a negative pressure, a non-flammable gas supply 263 configured to supply a non-flammable gas to at least the first space 261s, an exhauster 270 capable of exhausting a gas in the first space 261s and a gas in the second space 262s, and a pressure detector 280 configured to detect information, respectively, relating to a pressure in the first space 261s, a pressure in the second space 262s, and a pressure in the arrangement space 240s, the method including: during supply of the flammable gas, controlling at least one selected from the group of the non-flammable gas supply 263 and the exhauster 270 based on the information from the pressure detector 280 so as to adjust the pressure in the first space 261s to a positive pressure and adjust the pressure in the second space 262s to a pressure lower than the pressure in the arrangement space 240s or to a pressure higher than the pressure in the arrangement space 240s but lower than the pressure in the first space 261s. Even in this case, it is possible for the gas supply method to significantly reduce leakage of the flammable gas to an outside.

According to the present disclosure in some embodiments, it is possible to significantly reduce leakage of a flammable gas to an outside.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus, comprising:
a processing container capable of accommodating a substrate;
a flammable gas supply path configured to supply a flammable gas into the processing container;
a covering structure provided outside the processing container and configured to include an inner covering body including a first space for accommodating a portion of the flammable gas supply path and an outer covering body including a second space for accommodating the inner covering body;
an arrangement space adjusted to a negative pressure and in which the covering structure is arranged;
a non-flammable gas supply configured to supply a non-flammable gas to at least the first space;
an exhauster capable of exhausting a gas in the first space and a gas in the second space;
a pressure detector configured to detect information, respectively, relating to a pressure in the first space, a pressure in the second space, and a pressure in the arrangement space; and
a controller,
wherein, during supply of the flammable gas, the controller controls at least one selected from the group of the non-flammable gas supply and the exhauster based on the information from the pressure detector so as to adjust the pressure in the first space to a positive pressure and adjust the pressure in the second space to a pressure lower than the pressure in the arrangement space or to a pressure higher than the pressure in the arrangement space but lower than the pressure in the first space.

2. The substrate processing apparatus of claim 1, wherein the controller adjusts a flow rate of the non-flammable gas supplied by the non-flammable gas supply based on the information from the pressure detector.

3. The substrate processing apparatus of claim 1, wherein the controller determines whether or not the flammable gas leaks from the flammable gas supply path to the first space based on the information from the pressure detector, and stops the supply of the flammable gas through the flammable gas supply path when the controller has determined that the flammable gas leaks.

4. The substrate processing apparatus of claim 3, wherein the covering structure accommodates, in the first space, an on-off valve, a flow rate adjuster and a joint provided in the flammable gas supply path.

5. The substrate processing apparatus of claim 4, further comprising:
a gas box configured to form the arrangement space,
wherein pipes and valves are arranged inside the gas box and outside the covering structure.

6. The substrate processing apparatus of claim 1, wherein the exhauster includes a first path including an orifice capable of adjusting a flow rate of the gas exhausted from the first space, and a second path including a relief valve capable of being opened to exhaust the gas when the pressure in the first space reaches a predetermined level or higher.

7. The substrate processing apparatus of claim 1, wherein the non-flammable gas supply also supplies the non-flammable gas to the second space.

8. The substrate processing apparatus of claim 7, wherein at least one selected from the group of the non-flammable gas supply and the exhauster is adjusted to adjust the pressure in the second space to a positive pressure lower than the pressure in the first space.

9. The substrate processing apparatus of claim 1, wherein the covering structure accommodates, in the first space, an on-off valve, a flow rate adjuster and a joint provided in the flammable gas supply path.

10. A gas supply method for a substrate processing apparatus including a processing container capable of accommodating a substrate, a flammable gas supply path configured to supply a flammable gas into the processing container, a covering structure provided outside the processing container and configured to include an inner covering body including a first space for accommodating a portion of the flammable gas supply path and an outer covering body including a second space for accommodating the inner covering body, an arrangement space adjusted to a negative pressure and in which the covering structure is arranged, a non-flammable gas supply configured to supply a non-flammable gas to at least the first space, an exhauster capable of exhausting a gas in the first space and a gas in the second space, and a pressure detector configured to detect information, respectively, relating to a pressure in the first space, a pressure in the second space, and a pressure in the arrangement space, the gas supply method comprising:
during supply of the flammable gas, controlling at least one selected from the group of the non-flammable gas supply and the exhauster based on the information from the pressure detector so as to adjust the pressure in the first space to a positive pressure and adjust the pressure in the second space to a pressure lower than the pressure in the arrangement space or to a pressure higher than the pressure in the arrangement space but lower than the pressure in the first space.
